(19) United States
(12) Patent Application Publication
(10) Pub. No.: US 2026/0090252 A1
(43) Pub. Date: Mar. 26, 2026

(54) HARD COATING COMPOSITION AND ANTI-REFLECTION FILM INCLUDING A HARD COATING LAYER

(71) Applicant: Samsung Display Co., Ltd., Yongin-Si (KR)

(72) Inventor: Jong Hwan CHO, Yongin-si (KR)

(21) Appl. No.: 19/211,280

(22) Filed: May 19, 2025

(30) Foreign Application Priority Data
Sep. 25, 2024 (KR) 10-2024-0129751

(51) Int. Cl. H10K 59/80; C09D 7/62; C09D 179/04; C09D 183/06; G02B 1/111; G02B 1/14

(52) U.S. Cl. CPC H10K 59/879; C09D 7/62; C09D 179/04; C09D 183/06; G02B 1/111; G02B 1/14

(57) ABSTRACT

Provided is a hard coating composition and an anti-reflection film including a hard coating layer. Also provided is an anti-reflection film including a substrate; a hard coating layer on the substrate; and a refractive layer on the hard coating layer, wherein the hard coating layer may be formed of a polymer derived from a mixture containing silsesquioxane, an isocyanurate compound and inorganic particles surface-treated with silane having a fluorene skeleton.

This application claims priority from Korean Patent Application No. 10-2024-0129751 filed on Sep. 25, 2024 in the Korean Intellectual Property Office, the disclosure of which is incorporated herein by reference in its entirety.

### BACKGROUND

### 1. Field of the Disclosure

The present disclosure relates to a hard coating composition and an anti-reflection film including a hard coating layer, and more specifically, to a hard coating composition and an anti-reflection film including a hard coating layer formed using the same.

### 2. Description of the Related Art

As information-oriented society evolves, various demands for display devices are ever increasing. For example, display devices are being employed by a variety of electronic devices such as smart phones, digital cameras, laptop computers, navigation devices, and smart televisions.

Recently, in order to increase portability of the display device and provide a wider display screen, a bendable display device that allows the display area to be bent, and a foldable display device that allows the display area to be folded, are being released.

When a display device is used in an environment with a lot of ambient light from various illumination light sources and natural light, the image created displayed may not be clearly seen by the user due to reflected light, or may cause fatigue to the user's eyes. For these reasons, the demand for anti-reflection is increasing.

Methods for suppressing reflection of light may include: dispersing a filler such as inorganic fine particles in a resin, coating the resin on a base film, and providing roughness (anti-glare: AG coating); and forming a plurality of layers with different refractive indices on a base film and utilizing light interference (anti-reflection: AR coating); and a combination of the two. Among these, the AG coating can achieve low-reflection effect by reducing the amount of light that reaches the eyes by utilizing light scattering due to the roughness even though the absolute amount of reflected light is equivalent to that of typical hard coating. However, a shortcoming of the AG coating method is that the clarity of images is low because of surface roughness. Therefore, a lot of research has been conducted on the AR coating recently.

An anti-reflection film that is prepared by using the AR coating method typically has a multilayer structure in which a hard coating layer (high refractive layer), a low-reflection coating layer, or the like, are stacked on a substrate. The anti-reflection film may include multiple inorganic films of five or more layers in which high-refractive layers and low-refractive layers are alternately disposed as a low-reflection coating layer utilizing a distributed Bragg reflector (DBR). Unfortunately, such multiple inorganic films have a disadvantage in that the process of forming each layer is performed separately and thus the interlayer adhesion (interfacial adhesion) may become weak, resulting in cracks in a plurality of layers if the compressive stress increases.

### SUMMARY

Aspects of the present disclosure provide a hard coating layer and a hard coating composition for forming the hard coating layer that can effectively prevent reflection of light coming from the outside and prevent cracks in an anti-reflection film even if a display device is folded, even if the display device has few refractive layers on the hard coating layer.

It should be noted that the present disclosure is not limited to the effects and embodiments explicitly described herein. Other effects of the present disclosure will be apparent to those skilled in the art from the following descriptions.

According to an embodiment of the present disclosure, a hard coating composition including: a polymer represented by Chemical Formula 1 below:

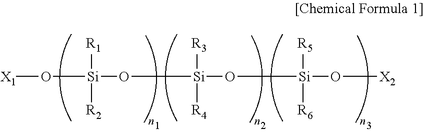

wherein at least two of R₁ to R₆ may be represented by Chemical Formula 2 or 3, at least one may be represented by Chemical Formula 4, the others may be each independently H, a substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, a substituted or unsubstituted silyl group or a hydroxy group, the X₁ and X₂ may be each independently H, halogen, a substituted or unsubstituted silyl group, and n₁, n₂ and n₃ may be each independently an integer of 1 to 100,

### [Chemical Formula 2]

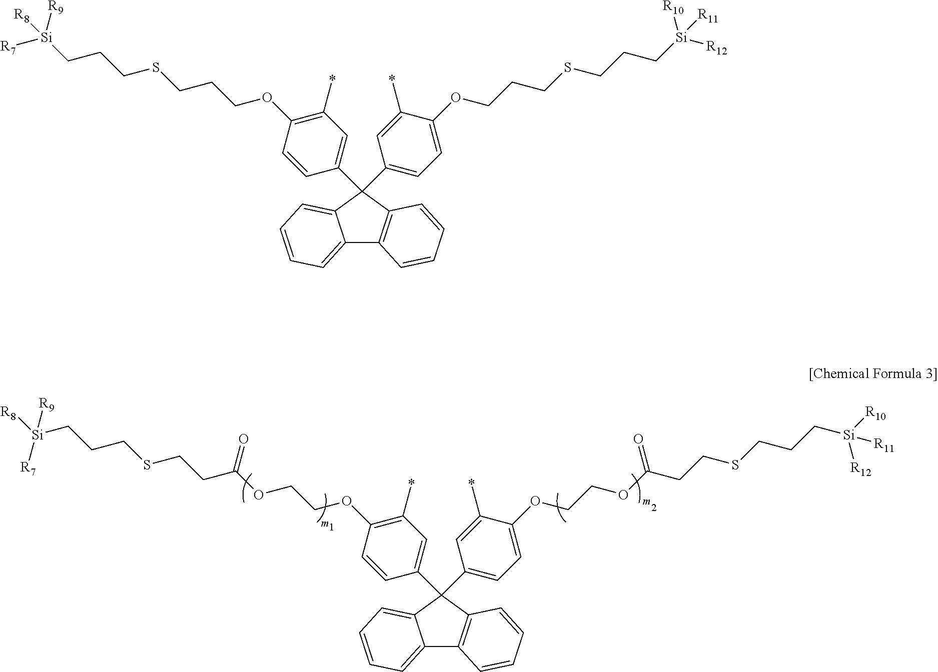

wherein R₇ to R₁₂ may be each independently H, a substituted or unsubstituted C₁-C₆ alkyl group, or a substituted or unsubstituted C₁-C₆ alkoxy group, R₇ to R₁₂ may be coupled with the inorganic particles, and each of m₁ and m₂ may independently be an integer from 1 to 10,

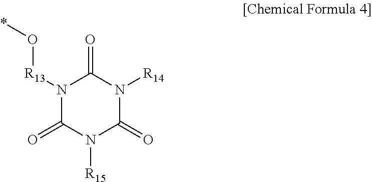

wherein R₁₃ may be a substituted or unsubstituted C₁-C₆ alkyl group, at least one of R₁₄ and R₁₅ may be

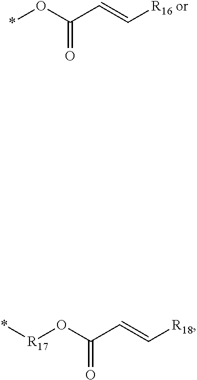

the other one may be

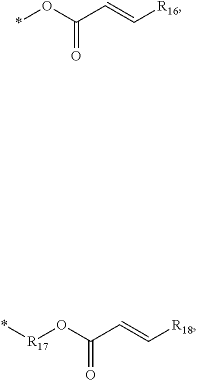

substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, or a substituted or unsubstituted C₄-C₁₀ acrylate, R₁₆ to R₁₈ may be each independently H, a substituted or unsubstituted C₁-C₆ alkyl group, a substituted or unsubstituted C₁-C₆ alkenyl group, or a substituted or unsubstituted C₄-C₁₀ acrylate.

The hard coating composition may further include at least one photoinitiator

The inorganic particles may include at least one of ZrO₂, SiO₂, TiO₂, Al₂O₃, ZnO, AlN, and Si₃N₄.

According to an embodiment of the present disclosure, an anti-reflection film including a substrate; a hard coating layer on the substrate; and a refractive layer on the hard coating layer, wherein the hard coating layer may be formed of a polymer derived from a mixture containing silsesquioxane, an isocyanurate compound and inorganic particles surface-treated with silane having a fluorene skeleton.

Ten to 20 parts by weight of the silsesquioxane; 10 to 20 parts by weight of the isocyanurate compound; 1 to 10 parts by weight of the silane having a fluorene skeleton; and 40 to 70 parts by weight of the inorganic particles are contained per 100 parts by weight of the polymer.

The polymer may further include at least one photoinitiator, wherein the photoinitiator comprises 1 to 5 parts by weight per 100 parts by weight of the polymer.

The silesesquioxane may have a random structure, a ladder structure or a cage structure.

The isocyanurate compound may have at least one acrylate functional group.

The isocyanurate compound may have at least one C₁-C₆ alcohol group.

The inorganic particles may include at least one of ZrO2, SiO₂, TiO₂, Al₂O₃, ZnO, AlN, and Si₃N₄.

A size of the inorganic particles ranges from 10 nm to 50 nm.
the silane may have the fluorene skeleton is represented by Chemical formula 5 or 6 below:

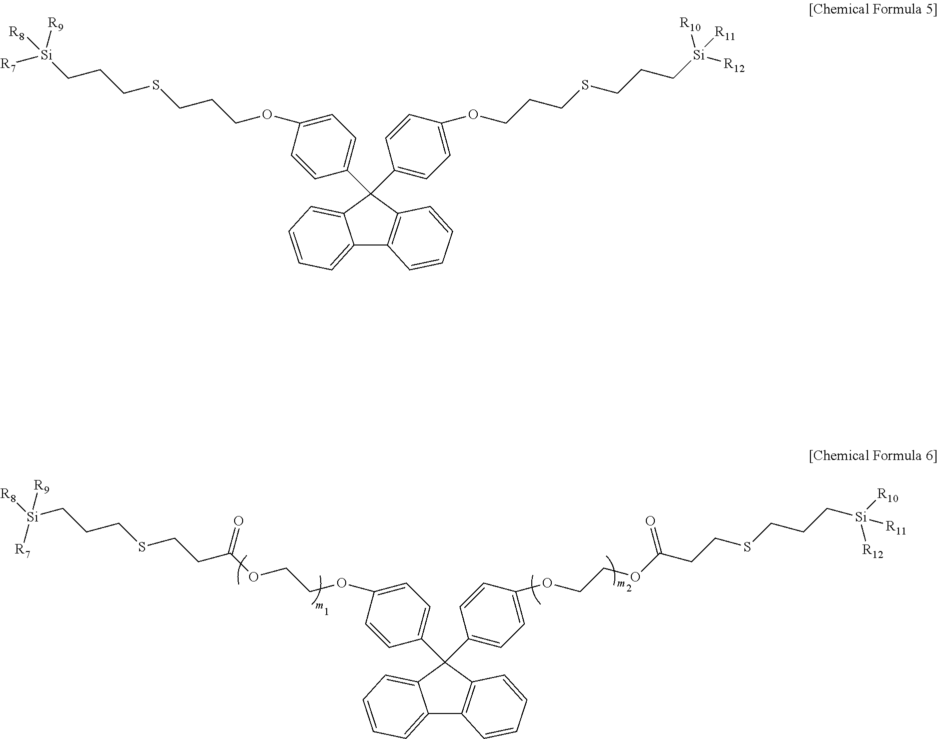

wherein each of R₇ to R₁₂ may independently be H, a substituted or unsubstituted C₁-C₆ alkyl group, or a substituted or unsubstituted C₁-C₆ alkoxy group, and each of m₁ and m₂ may independently be an integer from 1 to 10.

Each of R₇ to R₁₂ may independently be H, a methoxy group, or an ethoxy group.

The refractive layer includes a first layer, a second layer, and a third layer.

The anti-reflection film may have a reflectance of less than 1%.

The refractive index of the hard coating layer ranges from 1.55 to 1.8.

According to an embodiment of the present disclosure, an electronic device including a display panel; a window member on the display panel; and an anti-reflection film on the window member, wherein the anti-reflection film comprises: a substrate; a hard coating layer on the substrate; and a refractive layer on the hard coating layer, wherein the hard coating layer is formed of a polymer derived from a mixture containing silsesquioxane, an isocyanurate compound and inorganic particles surface-treated with silane having a fluorene skeleton.

The refractive layer may include a first layer, a second layer, and a third layer.

The anti-reflection film may have a reflectance of less than 1%.

The hard coating layer may have a refractive index of 1.55 to 1.8.

According to an embodiment of the present disclosure, by applying a hard coating layer having a high refractive index which is formed using a hard coating composition, a fewer number of refractive layers may be used on the hard coating layer to reduce the reflectance, so that it is possible to reduce the compressive stress of the anti-reflection film in case that a display device is folded and suppress cracks in the anti-reflection film. In addition, it is possible to simplify the process of fabricating an anti-reflection film and to save the fabrication cost.

It should be noted that effects of the present inventive concept are not limited to those described above and other effects of the present inventive concept will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment of the present disclosure in an unfolded state.

FIG. 2 is a perspective view showing the display device of FIG. 1 in a folded state.

FIG. 3 is a perspective view showing a display device according to another embodiment of the present disclosure in an unfolded state.

FIG. 4 is a perspective view showing the display device of FIG. 3 in a folded state.

FIG. 5 is a cross-sectional view showing a display device according to an embodiment of the present disclosure.

FIG. 6 is a schematic cross-sectional view of the display panel of FIG. 5.

FIG. 7 is a cross-sectional view showing an anti-reflection film in a display device according to a first embodiment of the present disclosure.

FIG. 8 is a cross-sectional view showing an anti-reflection film in a display device according to a second embodiment of the present disclosure.

FIG. 9 is a graph showing the refractive index versus zirconia (ZrO2) content of the hard coating layer composition used in forming a hard coating layer of an anti-reflection film in a display device according to an embodiment of the present disclosure.

FIG. 10 is a graph showing the reflectance versus the wavelength range of an anti-reflection film according to an embodiment of the present disclosure.

### DETAILED DESCRIPTION OF THE EMBODIMENTS

The features of the present disclosure, and the methods for achieving them, will become clear with reference to the embodiments described in detail below with the accompanying drawings. However, the present disclosure is not limited to the embodiments disclosed below, but may be implemented in various different forms, and these embodiments are provided only to make the disclosure of the present disclosure complete and to fully inform those skilled in the art of the disclosure of the scope of the disclosure, and the present inventive concept is defined by the scope of the claims.

Where a first element or layer is referred to as being “on” a second element or layer, the first element or layer may be disposed directly over the second element or layer, or indirectly through intervening element or layer. The same reference numerals refer to the same components throughout the specification. The shapes, sizes, ratios, angles, numbers, or the like disclosed in the drawings for explaining the embodiments are illustrative, and the present disclosure is not limited to the specific matters illustrated.

Although the terms “first” and “second” are used to describe various components, these components are not limited to a particular order or priority by these terms. These terms are used to primarily distinguish one component from another. Therefore, it goes without saying that the first component mentioned below may also be the second component within the technical concept of the present disclosure.

Hereinafter, embodiments of the present disclosure will be described in detail with reference to the accompanying drawings.

As used herein, the term alkyl may include linear or branched, saturated or unsaturated C₁-C₆ alkyl, and may include, but is not limited to, methyl, ethyl, propyl, butyl, pentyl, hexyl or all possible isomers thereof.

As used herein, the term halogen may represent an element of Group 17 of the Periodic Table, and may include, but is not limited to, F, Cl, Br, or I.

The features of each of the various embodiments of the present disclosure can be partially or wholly combined or combined with each other, and various technical connections and operations are possible. Each embodiment can be implemented independently of other embodiments or features from different embodiments may be implemented together.

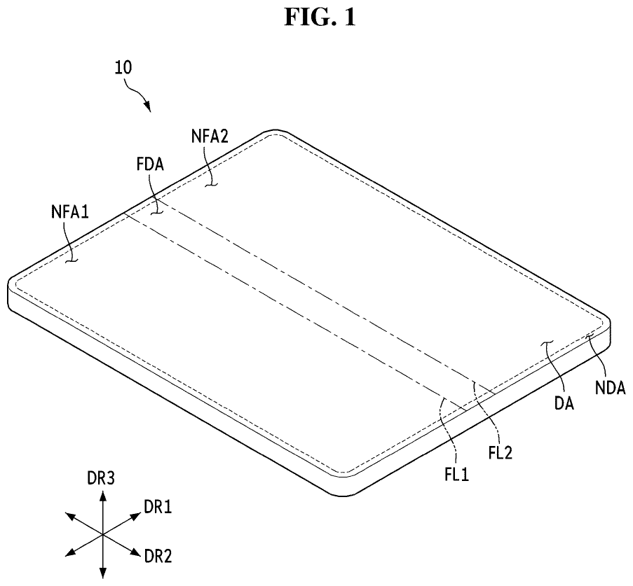

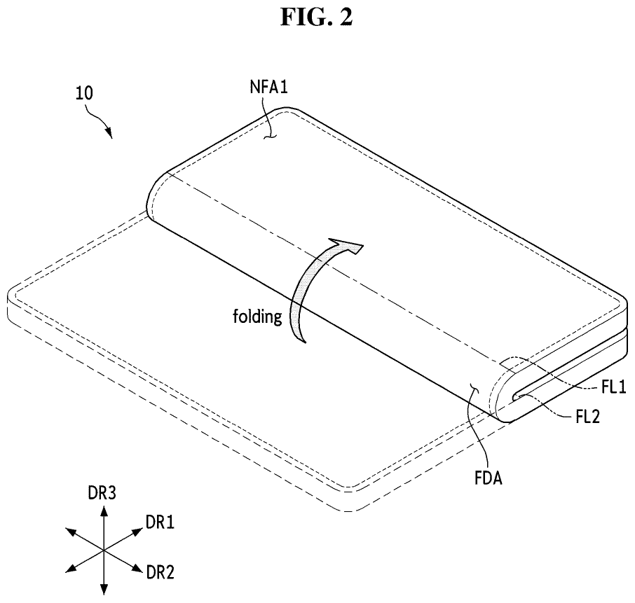

Hereinafter, embodiments of the present disclosure will be described in detail with reference to the accompanying drawings. FIG. 1 is a perspective view showing a display device according to an embodiment of the present disclosure in an unfolded state. FIG. 2 is a perspective view showing the display device of FIG. 1 in a folded state.

Referring to FIGS. 1 and 2, FIG. 1 shows a first state in which the display device 10 is not folded over the folding lines FL1 and FL2, and FIG. 2 shows a second state in which the display device 10 is folded over the folding lines FL1 and FL2.

A display device 10 according to the embodiment of the present disclosure is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things.

As shown in FIGS. 1 and 2, a first direction DR1 may refer to a direction parallel to a width of the display device 10, for example, the horizontal direction of the display device 10 if viewed from the top. A second direction DR2 may refer to a direction parallel to the length of the display device 10, for example the vertical direction of the display device 10 if viewed from the top. A third direction DR3 may refer to the thickness direction of the display device 10.

The display device 10 may have a quadrangular shape, such as a rectangular shape in case that viewed from the top. Each of the corners of the display device 10 may form a right angle or may be a rounded corner. The front surface of the display device 10 may include two shorter sides extended in the first direction DR1 and two longer sides extended in the second direction DR2.

The display device 10 may include the display area DA and a non-display area NDA. The shape of the display area DA may be similar to the shape of the display device 10 if viewed from the top. For example, in case that the display device 10 has a rectangular shape viewed from the top, the display area DA may also have a rectangular shape viewed from the top.

The display area DA may include a plurality of pixels to display images. The non-display area NDA may not include pixels and thus may not display images. The non-display area NDA may be disposed around the display area DA. The non-display area NDA may surround the display area DA, but the embodiments of the present disclosure are not limited thereto. The display area DA may be at least partially surrounded by the non-display area NDA.

The display device 10 may stay unfolded in a first state or folded or bent in a second state. The display device 10 may be folded inward (herein referred to as “in-folded”) so that the two front surfaces of the display device DA in the unfolded state face each other, as shown in FIG. 2. In this in-folded instance, a part of the front surface of the display device 10 may face, even contacts, the other part of the front surface. Alternatively, the display device 10 may be folded outward (herein referred to as “out-folded”) such that a part of the rear surface faces, even contacts, the other part of the rear surface in the folded state.

The display device 10 may include a folding area FDA, a first non-folding area NFA1, and a second non-folding area NFA2. The display device 10 can be bent or folded at the folding area FDA, while it cannot be bent or folded at the first non-folding area NFA1 and the second non-folding area NFA2. According to an embodiment of the present disclosure, the first non-folding area NFA1 and the second non-folding area NFA2 may be flat areas of the display device 10.

The first non-folding area NFA1 may be on one side, for example, the left side of the folding area FDA. The second non-folding area NFA2 may be on the opposite side, for example, the right side of the folding area FDA. The folding area FDA may be defined by the first folding line FL1 and the second folding line FL2, and the display device 10 can be bent with a predetermined curvature between the first folding line FL1 and the second folding line FL2. The first folding line FL1 may be the boundary between the folding area FDA and the first non-folding area NFA1, and the second folding line FL2 may be the boundary between the folding area FDA and the second non-folding area NFA2.

The first folding line FL1 and the second folding line FL2 may extend in the second direction DR2 as shown in FIGS. 1 and 2, and the display device 10 may be folded with respect to a folding axis extending in the second direction DR2. Accordingly, the width of the display device 10 in the first direction DR1 can be reduced to about half, making the display device 10 easy to carry.

When the first folding line FL1 and the second folding line FL2 extend in the second direction DR2 as shown in FIGS. 1 and 2, the length of the folding area FDA in the second direction DR2 may be greater than the width in the first direction DR1. In addition, the length of the first non-folding area NFA1 in the second direction DR2 may be greater than the width of the first non-folding area NFA1 in the first direction DR1. The length of the second non-folding area NFA2 in the second direction DR2 may be greater than the width of the second non-folding area NFA2 in the first direction DR1.

Each of the display area DA and the non-display area NDA may overlap at least one of the folding area FDA, the first non-folding area NFA1, and the second non-folding area NFA2. In the example shown in FIGS. 1 and 2, each of the display area DA and the non-display area NDA overlaps the folding area FDA, the first non-folding area NFA1 and the second non-folding area NFA2.

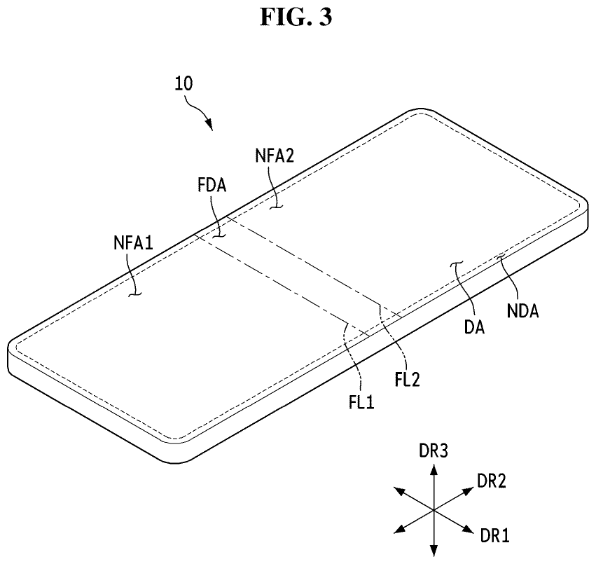

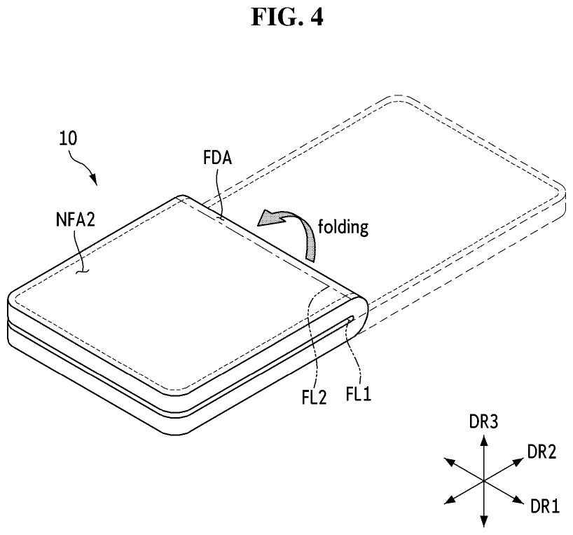

FIG. 3 is a perspective view showing a display device according to another embodiment of the present disclosure in an unfolded state. FIG. 4 is a perspective view showing the display device of FIG. 3 in a folded state.

The embodiment of FIGS. 3 and 4 is substantially identical to the embodiment of FIGS. 1 and 2 except that a first folding line FL1 and a second folding line FL2 extend in the first direction DR1 and a display device 10 can be folded with respect to a folding axis that extends in the first direction DR1. When folded, the length of the display device 10 in the second direction DR2 can be reduced to approximately half. Elements of FIGS. 3 and 4 identical to those of FIGS. 1 and 2 will not be described to avoid redundancy.

Referring to FIGS. 3 and 4, FIG. 3 shows a first state in which the display device 10 is not folded over the folding lines FL1 and FL2, and FIG. 4 shows a second state in which the display device 10 is folded over the folding lines FL1 and FL2.

In the first state in which the display device 10 is unfolded, the length of the display device 10 extending in the second direction DR2 may be longer than the width of the display device 10 extending in the first direction DR1.

The first folding line FL1 and the second folding line FL2 may extend in the first direction DR1 as shown in FIGS. 3 and 4, and the display device 10 may be folded in with respect to a folding axis extending in the first direction DR1.

The first non-folding area NFA1 may be on one side, for example, the first side of the folding area FDA. The second non-folding area NFA2 may be on the opposite side, for example, the second side of the folding area FDA.

In case that the first folding line FL1 and the second folding line FL2 extend in the first direction DR1 as shown in FIGS. 3 and 4, the width of the folding area FDA in the first direction DR1 may be greater than the length in the second direction DR2. For the first non-folding area NFA1, the length in the second direction DR2 may be greater than the width of the first non-folding area NFA1 in the first direction DR1. For the second non-folding area NFA2, the length in the second direction DR2 may be greater than the width of the second non-folding area NFA2 in the first direction DR1.

In the following description, the embodiment of FIGS. 3 and 4 will be described as an example for convenience of illustration, but the present disclosure is not limited thereto. For example, the following description may be equally applied to the embodiment of FIGS. 1 and 2.

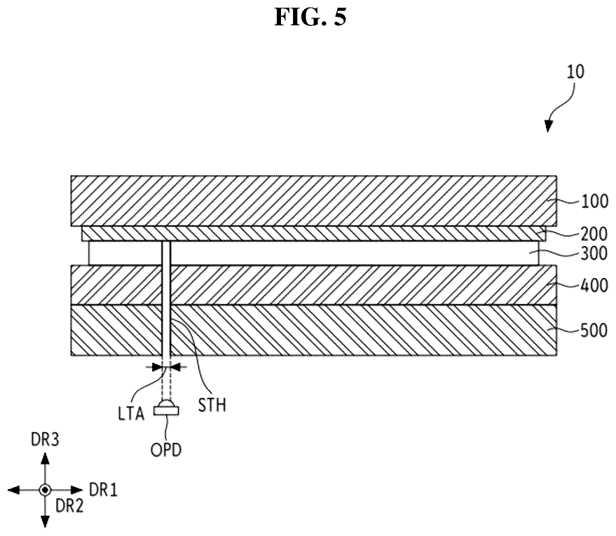

FIG. 5 is a cross-sectional view showing a display device according to an embodiment of the present disclosure.

Referring to FIG. 5, a display device 10 according to an embodiment of the present disclosure may include an anti-reflection film 100, a window member 200, a first adhesive member 300, an upper protective member 400, and a display panel 500.

Initially, the display panel 500 may be a panel for displaying images. The display panel 500 may be an organic light-emitting display panel including an organic light-emitting layer, a quantum-dot light-emitting display panel including a quantum-dot light-emitting layer, an inorganic light-emitting display panel using inorganic semiconductor elements as the light-emitting elements, and a micro light-emitting display panel using micro light-emitting diodes as the light-emitting elements. In the following description, an organic light-emitting display panel is employed as the display panel 500. It is, however, to be understood that the present disclosure is not limited thereto.

The display panel 500 may include a light transmission area LTA overlapping an optical device OPD in the third direction DR3. The optical device OPD is an optical sensor that detects light, and may be, for example, a camera sensor, a proximity sensor, and an illuminance sensor. The light transmission area LTA may be a part of the display area DA.

The light transmission area LTA may include a transmissive area that allows light to pass. Alternatively, the light transmission area LTA may be a through hole extending through the display panel. The transmittance of the light transmission area LTA may be higher than the transmittance of the display area DA excluding the light transmission area LTA. In addition, due to the transmissive area of the light transmission area LTA, the density or integration degree of pixels in the light transmission area LTA may be lower than the density or integration degree of pixels in the display area DA excluding the light transmission area LTA. For example, the number of pixels per unit area in the light transmission area LTA may be lower than the number of pixels per unit area in the display area DA outside of the light transmission area LTA. Alternatively, pixels per inch (PPI) in the light transmission area LTA may be a smaller number than PPI in the display area DA outside of the light transmission area LTA.

The upper protective member 400 may be on the front surface of the display panel 500. The upper protective member 400 can mitigate shock to protect the display panel 500 from external impact. For example, the upper protective member 400 may include a material having high flexibility and high rigidity.

The window member 200 may be attached to the front surface of the upper protection member 400 by the first adhesive member 300. The window member 200 is made of a transparent material, and may be, for example, glass or plastic. For example, the window member 200 may be an ultra thin glass (UTG) having a thickness of 0.1 mm or less or a transparent polyimide film.

The first adhesive member 300 may be a transparent adhesive film or a transparent adhesive resin. For example, the first adhesive member 300 may include a transparent adhesive such as a pressure sensitive adhesive (PSA) and an optically clear adhesive (OCA). The first adhesive member 300 may include an acrylic adhesive material.

The anti-reflection film 100 may be on the front surface of the window member 200. The anti-reflection film 100 may include a plurality of refractive layers having different refractive indices. The anti-reflection film 100 can reduce reflected light through the plurality of refractive layers. The anti-reflection film 100 is a key feature of the present disclosure, and will be described in detail later.

A light-blocking layer (not shown) for absorbing light incident from the outside, a buffer layer (not shown) for absorbing impact from the outside, and a heat-dissipation layer for efficiently discharging heat from the display panel 500 may be further included under the display panel 500.

The light-blocking layer can block transmission of light, thereby preventing elements disposed under the light-blocking layer from being seen from above the display panel 500. The light-blocking layer may include a light-absorbing material such as black pigment and black dye.

The buffer layer can absorb external shock to prevent the display panel 500 from being damaged. The buffer layer may be made up of a single layer or multiple layers. For example, the buffer layer may include a polymer resin such as polyurethane, polycarbonate, polypropylene and polyethylene, or may be include a material having elasticity such as a rubber and a sponge obtained by foaming a urethane-based material or an acrylic-based material.

The heat sink layer may include a first heat dissipation layer including graphite or carbon nanotubes, and a second heat dissipation layer may include a thin metal film such as copper, nickel, ferrite and silver, which can block electromagnetic waves and have high thermal conductivity.

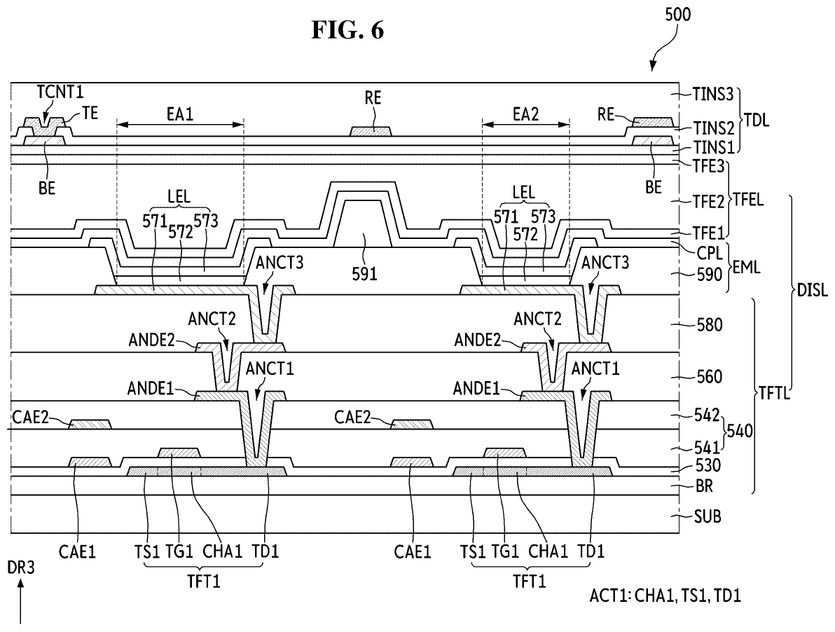

FIG. 6 is a schematic cross-sectional view of the display panel 500 of FIG. 5.

Referring to FIG. 6, the display panel 500 may include a substrate SUB, a display layer DISL on the substrate SUB, and a touch detecting layer TDL disposed on the display layer DISL. The display layer DISL may include a thin-film transistor layer TFTL, an emission material layer EML, and an encapsulation layer TFEL.

The thin-film transistor layer TFTL may be on the substrate SUB. The thin-film transistor layer TFTL may include a barrier layer BR, a thin-film transistor TFT1, a first capacitor electrode CAE1, a second capacitor electrode CAE2, a first anode connection electrode ANDE1, a second anode connection electrode ANDE2, a gate insulator 530, a first interlayer dielectric film 541, a second interlayer dielectric film 542, a first planarization film 560, a second planarization film 580.

The substrate SUB may be made of an insulating material such as a polymer resin. For example, the substrate SUB may be made of polyimide. The substrate SUB may be a flexible substrate that can be bent, folded, or rolled.

The barrier film BR may be on the substrate SUB. The barrier film BR is a film for protecting the thin-film transistors of the thin-film transistor layer TFTL and an emissive layer 572 of the emission material layer EML. The barrier film BR may be made up of multiple inorganic films stacked on one another in an alternating manner. For example, the barrier film BR may be made up of multiple layers in which one or more inorganic layers of a silicon nitride layer, a silicon oxynitride layer, a silicon oxide layer, a titanium oxide layer and an aluminum oxide layer are alternately stacked on one another.

The thin-film transistors TFT1 may be on the barrier film BR. An active layer ACT1 of the thin-film transistor TFT1 may be on the barrier layer BR. The active layer ACT1 of the thin-film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1 and a drain region TD1. The channel region CHA1 may overlap with a gate electrode TG1 in the third direction DR3 that is the thickness direction of the substrate SUB. The source region TS1 may be on one side of the channel region CHA1, and the drain region TD1 may be on the opposite side of the channel region CHA1. The source region TS1 and the drain region TD1 may not overlap with the gate electrode TG1 in the third direction DR3. The source region TS1 and the drain region TD1 may be formed by doping a silicon semiconductor or an oxide semiconductor with ions or impurities to have conductivity.

The gate insulator 530 may be on the active layer ACT1 of the thin-film transistor TFT1. The gate insulator 530 may include an inorganic layer, for example, a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be on the gate insulator 530. The gate electrode TG1 may overlap with the channel region CHA1 in the third direction DR3. Although the gate electrode TG1 and the first capacitor electrode CAE1 are spaced apart from each other in the example shown in FIG. 6, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 541 may be on the gate electrode TG1 of the thin-film transistor TFT1 and the first capacitor electrode CAE1. The first interlayer dielectric film 541 may include an inorganic layer, for example, a silicon nitride layer, a silicon oxynitride layer, a silicon oxide layer, a titanium oxide layer, or an aluminum oxide layer. The first interlayer dielectric film 541 may be made of a plurality of inorganic films.

The second capacitor electrode CAE2 may be on the first interlayer dielectric layer 541. The second capacitor electrode CAE2 may overlap the first capacitor electrode CAE1 of the thin-film transistor TFT1 in the third direction DR3. In addition, if the gate electrode TG1 and the first capacitor electrode CAE1 are formed as a single piece, the second capacitor electrode CAE2 may overlap the gate electrode TG1 in the third direction DR3. Because the first interlayer dielectric layer 541 has a predetermined dielectric constant, a capacitor can be formed by the first capacitor electrode CAE1, the second capacitor electrode CAE2 and the first interlayer dielectric layer 541 disposed therebetween. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 542 may be disposed over the second capacitor electrode CAE2. The second interlayer dielectric film 542 may include an inorganic layer, for example, a silicon nitride layer, a silicon oxynitride layer, a silicon oxide layer, a titanium oxide layer, or an aluminum oxide layer. The second interlayer dielectric film 542 may be made of a plurality of inorganic films.

A first anode connection electrode ANDE1 may be on the second interlayer dielectric film 542. The first anode connection electrode ANDE1 may be connected to the drain electrode TD1 of the thin-film transistor TFT1 through a first connection contact hole ANCT1 that extends through the gate insulator 530, the first interlayer dielectric film 541 and the second interlayer dielectric film 542. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first planarization film 560 may be disposed over the first anode connection electrode ANDE1 for providing a flat surface over level differences due to the thin-film transistor TFT1. The first planarization film 560 may include an organic layer such as an acryl resin, an epoxy resin, a phenolic resin, a polyamide resin and a polyimide resin.

A second anode connection electrode ANDE2 may be on the first planarization layer 560. The second anode connection electrode ANDE2 may be connected to the first anode connection electrode ANDE1 through a second connection contact hole ANCT2 extending through the first planarization layer 560. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second planarization film 580 may be on the second anode connection electrode ANDE2. The second planarization film 180 may be formed as an organic layer such as an acryl resin, an epoxy resin, a phenolic resin, a polyamide resin and a polyimide resin.

An emission material layer EML including light-emitting elements LEL and a bank 590 may be on the second planarization film 580. Each of the light-emitting elements LEL includes a pixel electrode 571, an emissive layer 572, and a common electrode 573.

The pixel electrode 571 may be on the second planarization film 580. The pixel electrode 571 may be connected to the second anode connection electrode ANDE2 through a third connection contact hole ANCT3 extending through the second planarization film 580.

In the top-emission structure in which light exits from the emissive layer 572 toward the common electrode 573, the pixel electrode 571 may be made of a metal material having a high reflectivity such as a stack structure of aluminum and titanium (Ti/Al/Ti), a stack structure of aluminum (Al) and ITO (Indium Tin Oxide) (ITO/Al/ITO), an APC alloy and a stack structure of an APC alloy and ITO (ITO/APC/ITO). The APC alloy is an alloy of silver (Ag), palladium (Pd) and copper (Cu).

The bank 590 may partition the pixel electrode 571 on the second planarization film 580 to define the emission areas EA1 and EA2. The bank 590 may be disposed to cover the edges of the pixel electrode 571. The bank 590 may include an organic film such as an acryl resin, an epoxy resin, a phenolic resin, a polyamide resin and a polyimide resin.

In each of the first emission area EA1 and the second emission area EA2, the pixel electrode 571, the emissive layer 572 and the common electrode 573 are stacked on one another sequentially, so that holes from the pixel electrode 571 and electrons from the common electrode 573 are recombined with each other in the emissive layer 572 to emit light.

The emissive layer 571 may be on the pixel electrode 572 and the bank 590. The emissive layer 572 may include an organic material to emit light of a certain color. For example, the emissive layer 572 may include a hole transporting layer, an organic material layer, and an electron transporting layer.

The common electrode 573 may be on the emissive layer 572. The common electrode 573 may be disposed to cover the emissive layer 572. The common electrode 573 may be a common layer formed commonly across the first emission area EA1 and the second emission area EA2.

In the top-emission organic light-emitting diode, the common electrode 573 may include a transparent conductive material (TCP) such as ITO and IZO that can transmit light, or a semi-transmissive conductive material such as magnesium (Mg), silver (Ag) and an alloy of magnesium (Mg) and silver (Ag). If the common electrode 173 includes a semi-transmissive metal material, the light extraction efficiency can be increased by using microcavities.

A spacer 591 may be on the bank 590. The spacer 591 may support a mask during a process of fabricating the emission layer 572. The spacer 591 may include an organic layer such as an acryl resin, an epoxy resin, a phenolic resin, a polyamide resin and a polyimide resin.

According to some embodiments of the present disclosure, the display panel 500 may further include a capping layer CPL on the common electrode 573. The capping layer CPL may be made of an inorganic material. For example, the capping layer CPL may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride.

An encapsulation layer TFEL may be on the common electrode 573. The encapsulation layer TFEL may include at least one inorganic layer to prevent permeation of oxygen or moisture into the emission material layer EML. In addition, the encapsulation layer TFEL may include at least one organic film to protect the emission material layer EML from particles such as dust. For example, the encapsulation layer TFEL may include a first inorganic encapsulation layer TFE1, an organic encapsulation layer TFE2 and a second inorganic encapsulation layer TFE3.

The first inorganic encapsulation film TFE1 may be on the common electrode 573, the organic encapsulation film TFE2 may be on the first inorganic encapsulation film TFE1, and the second inorganic encapsulation film TFE3 may be on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, or the like.

A touch detecting layer TDL may be on the encapsulation layer TFEL. The touch detecting layer TDL includes a first touch insulating film TINS1, connection electrodes BE, a second touch insulating film TINS2, the driving electrodes TE, the sensing electrodes RE, and a third touch insulating film TINS3.

The first touch insulating film TINS1 may be on the encapsulation layer TFEL. The first touch insulating film TINS1 may include an inorganic film, for example, a silicon nitride layer, a silicon oxynitride layer, a silicon oxide layer, a titanium oxide layer, or an aluminum oxide layer.

The connection electrode BE may be on the first touch insulating film TINS1. The connection electrode BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be over the connection electrodes BE. The second touch insulating layer TINS2 may include an inorganic layer, for example, a silicon nitride layer, a silicon oxynitride layer, a silicon oxide layer, a titanium oxide layer, or an aluminum oxide layer. Alternatively, the second touch insulating layer TINS2 may include an organic layer such as an acryl resin, an epoxy resin, a phenolic resin, a polyamide resin and a polyimide resin.

The driving electrodes TE and the sensing electrodes RE may be on the second touch insulating film TINS2. The driving electrodes TE and the sensing electrodes RE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The driving electrodes TE and the sensing electrodes RE may overlap with the connection electrodes BE in the third direction DR3. The driving electrodes TE may be connected to the connection electrodes BE through touch contact holes TCNT1 extending through the first touch insulating film TINS1.

The third touch insulating film TINS3 may be formed on the driving electrodes TE and the sensing electrodes RE. The third touch insulating layer TINS3 may provide a flat surface over the driving electrodes TE, the sensing electrodes RE and the connection electrodes BE which having different heights. The third touch insulating film TINS3 may be include an organic layer such as an acryl resin, an epoxy resin, a phenolic resin, a polyamide resin and a polyimide resin.

Hereinafter, various embodiments of an anti-reflection film 100 according to an embodiment of the present disclosure will be described with reference to the accompanying drawings.

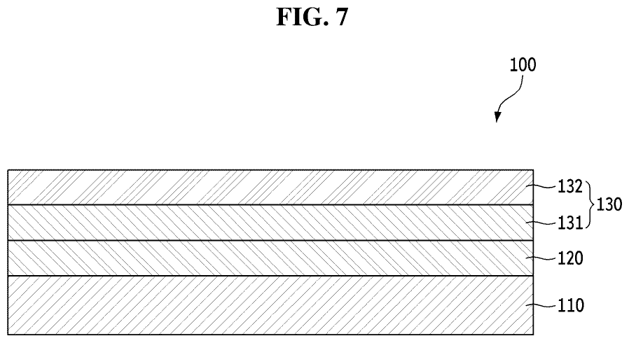

FIG. 7 is a cross-sectional view showing an anti-reflection film in a display device according to a first embodiment of the present disclosure.

Referring to FIG. 7, the anti-reflection film 100 according to the first embodiment may include a substrate 110, a hard coating layer 120, and a refractive layer 130.

The substrate 110 may be a window member 200. That is to say, the hard coating layer 120 may be on the window member 200. The hard coating layer 120 may protect the window member 200 from external impact. The hard coating layer 120 may have a higher strength than the window member 200. The hard coating layer 120 can prevent damages such as fine cracks, dents, and deformation resulting from being pressed or impacted from the outside.

The substrate 110 may be implemented as a separate substrate. The substrate may be a plastic, glass, or metal substrate.

The anti-reflection film 100 according to the embodiment will be described later in detail. Hereinafter, a hard coating composition forming the hard coating layer 120 included in the anti-reflection film 100 according to the embodiment will be described below.

The hard coating composition may include a polymer derived from a mixture containing silsesquioxane, an isocyanurate compound and inorganic particles surface-treated with silane having a fluorene skeleton. The hard coating composition may include a polymer unit derived from a mixture containing silsesquioxane, an isocyanurate compound and inorganic particles surface-treated with silane having a fluorene skeleton.

The silsesquioxane may include a random structure, a ladder structure or a cage structure. 10 to 20 parts by weight of the silsesquioxane may be contained per 100 parts by weight of the polymer included in the hard coating composition. If the content of the silsesquioxane is less than 10 parts by weight, the flexibility of the hard coating layer formed using the hard coating composition may not be improved. If the content of the silsesquioxane is greater than 20 parts by weight per 100 parts by weight of the polymer included in the hard coating composition, the surface hardness of the hard coating layer include the hard coating composition may be lowered.

The isocyanurate compound may have at least one acrylate functional group.

The isocyanurate compound may have at least one C₁-C₆ alcohol group. For example, the isocyanurate compound may have at least one of methanol, ethanol, propanol, butanol, pentanol or hexanol. For example, the isocyanurate compound may have a hydroxyl group as a terminal group. The hydroxy group may form a crosslink with the silsesquioxane.

The isocyanurate compound may include at least one of: (2-[3-(2-hydroxyethyl)-2,4,6-trioxo-5-(2-prop-2-enoyloxyethyl)-1,3,5-triazinan-1-yl]ethyl prop-2-enoate); bis(acryloxyethyl)hydroxyethyl isocyanurate; and bis(methacryloxyethyl)hydroxyethyl isocyanurate.

Ten to 20 parts by weight of the isocyanurate compound may be contained per 100 parts by weight of the polymer included in the hard coating composition. If the content of the isocyanurate compound is less than 10 parts by weight, the surface hardness and strength of the hard coating layer 120 may be lowered. If the content of the isocyanurate compound is greater than 20 parts by weight, the brittleness of the hard coating layer 120 may increase, and accordingly the flexibility may be reduced and cracks may increase in case that the hard coating layer is bent.

The mixture forming the polymer included in the hard coating composition may include surface-treated inorganic particles. The inorganic particles may be surface-treated with silane having a fluorene skeleton.

The inorganic particles may be spherical and may have a substantially monodispersed size distribution or a polydispersed distribution obtained by mixing a plurality of particles having a monodispersed distribution. For example, the average size of the inorganic particles may range from 10 nm to 50 nm. The average size of the inorganic particles may represent the average diameter of the inorganic particles. For example, the average diameter of the inorganic particles may range from 10 nm to 50 nm.

If the average size of the inorganic particles exceeds 50 nm in diameter, the optical transparency of the hard coating layer including the hard coating composition according to the embodiment of the present disclosure may be reduced. If the average size of the inorganic particles is less than 10 nm, the surface hardness cannot be improved sufficiently and the refractive index may be lowered.

The inorganic particles may be at least one of ZrO₂, SiO₂, TiO₂, Al₂O₃, ZnO, AlN, and Si₃N₄.

The inorganic particles surface-treated with the silane having a fluorene skeleton can increase the content of inorganic particles in the hard coating composition due to compatibility with silsesquioxane increased by surface modification. Therefore, the hard coating composition according to the embodiment of the present disclosure can form a hard coating layer with improved surface hardness, strength and refractive index by way of including the inorganic particles surface-treated with the silane having a fluorene skeleton to thereby increase the proportion of inorganic particles.

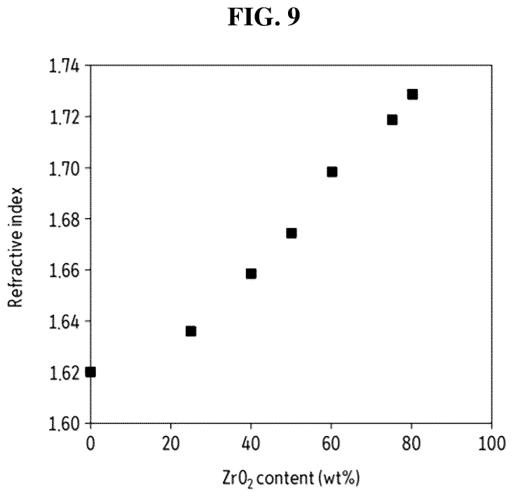

FIG. 9 is a graph showing the refractive index versus zirconia (ZrO₂) content of the hard coating layer composition used in forming a hard coating layer of an anti-reflection film in a display device according to an embodiment of the present disclosure.

Referring to FIG. 9, it can be seen that the refractive index increases as the content of zirconia used as the inorganic particle increases.

Forty to 70 parts by weight of the inorganic particles may be contained per 100 parts by weight of the polymer included in the hard coating composition. If the content of the inorganic particles is less than 40 parts by weight, the refractive index of the hard coating layer may decrease, lowering the surface hardness and strength. If the content of the inorganic particles exceeds 70 parts by weight, cracks may increase upon bending the hard coating layer.

In the hard coating composition, the inorganic particles surface-treated with silane having a fluorene skeleton may be bonded to silsesquioxane and provided as a polymer formed integrally.

The silane having a fluorene skeleton may be represented by Chemical Formula 5 or 6 below:

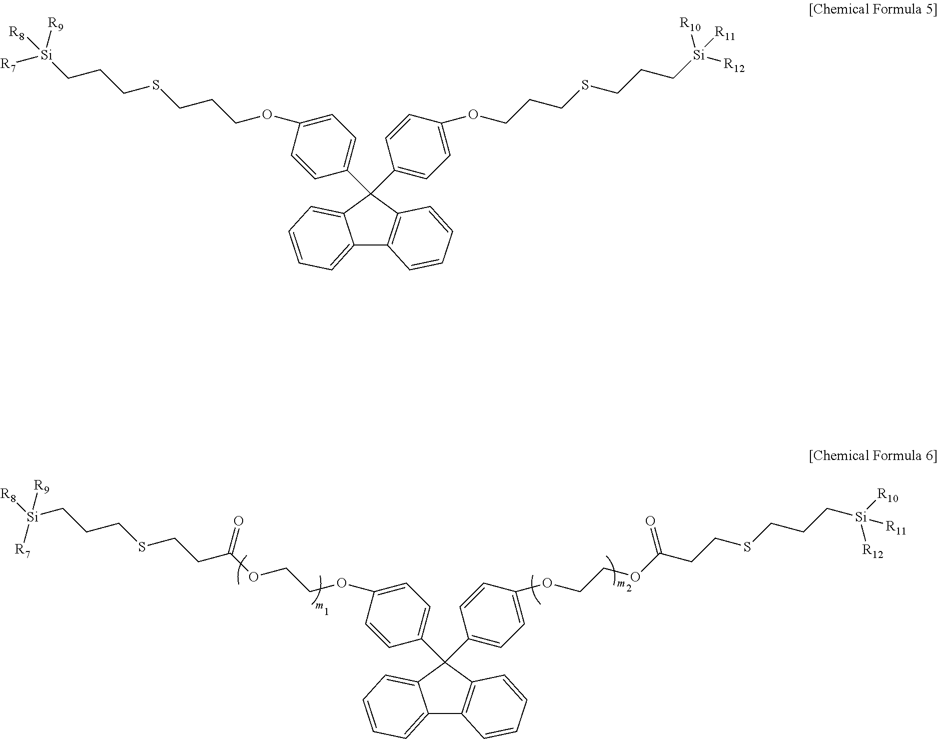

where R₇ to R₁₂ may be H, a substituted or unsubstituted C₁-C₆ alkyl group, or a substituted or unsubstituted C₁-C₆ alkoxy group, and m₁ and m₂ may be an integer from 1 to 10.

Each of R₇ to R₁₂ may be H, a methoxy group, or an ethoxy group.

In the silane having a fluorene skeleton, SiR₇₋₉ and SiR₁₀₋₁₂ may be coupled with inorganic particles.

1 to 10 parts by weight of the silane having a fluorene skeleton may be contained per 100 parts by weight of the polymer included in the hard coating composition. If the content of the silane having a fluorene skeleton is less than 1 part by weight, the bonding strength between the inorganic particles and the silsesquioxane may decrease.

The sum of m₁ and m₂ may be between 2 and 20. As the sum of m₁ and m₂ increases, the flexibility of the hard coating layer may increase.

The hard coating composition may include a polymer formed as a mixture reacts, which contains silsesquioxane, an isocyanurate compound and inorganic particles surface-treated with silane having a fluorene skeleton.

The hard coating composition according to an embodiment may include a polymer represented by Chemical Formula 1 below:

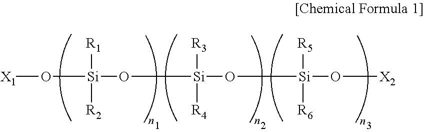

where at least two of R₁ to R₆ are represented by Chemical Formula 2 or 3, at least one is represented by Chemical Formula 4, the others are H, a substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, a substituted or unsubstituted silyl group or a hydroxy group, X₁ and X₂ are H, halogen, a substituted or unsubstituted silyl group, and n₁, n₂ and n₃ are an integer of 1 to 100.

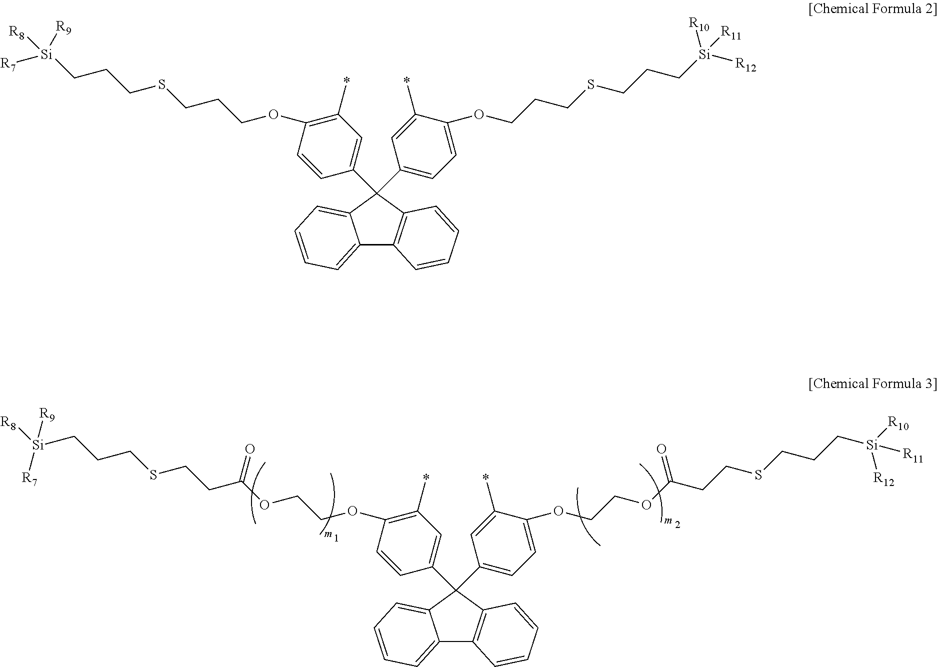

where R₇ to R₁₂ may be H, a substituted or unsubstituted C₁-C₆ alkyl group, or a substituted or unsubstituted C₁-C₆ alkoxy group, R₇ to R₁₂ may be coupled with the inorganic particles, and m₁ and m₂ may be an integer from 1 to 10.

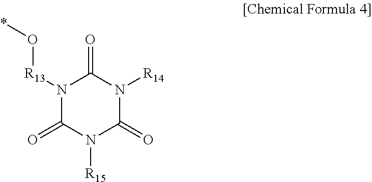

where R₁₃ may be a substituted or unsubstituted C₁-C₆ alkyl group, at least one of R₁₄ and R₁₅ may be

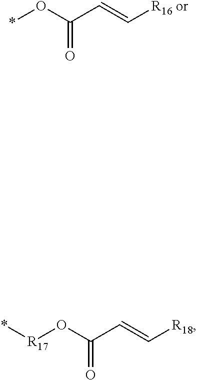

the other one may be

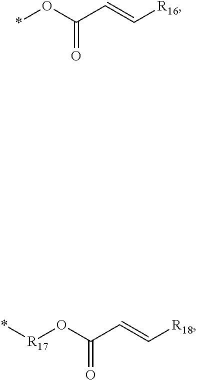

a substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, or a substituted or unsubstituted C₄-C₁₀ acrylate, R₁₆ to R₁₈ may be H, a substituted or unsubstituted C₁-C₆ alkyl group, a substituted or unsubstituted C₁-C₆ alkenyl group, or a substituted or unsubstituted C₄-C₁₀ acrylate.

The isocyanurate compound combined with the silsesquioxane may be represented by Chemical Formula 4 above.

The silane having a fluorene skeleton bonded with the silsesquioxane may be represented by Chemical Formula 2 and/or 3 above.

As used herein, the expression “substituted or unsubstituted” may mean substituted or unsubstituted with at least one substituent selected from the group consisting of: hydrogen, halogen, cyano group, nitrile group, nitro group, amino group, silyl group, boron group, phosphine oxide group, alkyl group, alkenyl group, fluorenyl group, aryl group, and hetero group.

As used herein, the symbol -* indicates a connection position. The connection may mean a chemical bond.

Chemical Formula 1 may represent a polymer derived from a mixture containing silsesquioxane, an isocyanurate compound and inorganic particles surface-treated with silane having a fluorene skeleton.

According to an embodiment of the present disclosure, the hard coating composition may further include at least one photoinitiator.

The photoinitiator may include at least one of: an acetophenone-based photoinitiator, a benzophenone-based photoinitiator, a thioxanthone-based photoinitiator, a benzoin-based photoinitiator, and a triazine-based photoinitiator.

The photoinitiator may include at least one of: α-hydroxy ketone, 2,2-dimethoxyl,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, 2-hydroxy-1-{4-[4-(2-hydroxy-2-methyl-propionyl) -benzyl]-phenyl}-2-methylpropan-1-one,phenylglyoxylate, 2-methyl-1[4-(methylthio)phenyl]-2-morpholinopropan-1-one, 2-benzyl-2-dimethylamino-1-(4-morpholinophenyl)-butanone-1, 2-dimethylamino-2-(4-methyl-benzyl)-1-(4-morpholin-4-yl-phenyl)-butanl-one, 2,4,6-trimethylbenzoyl-diphenylphosphine oxide, 2,4,6-trimethylbenzoyl -diphenyl phosphinate, bis(2,4,6-trimethylbenzoyl)-phenylphosphineoxide, [1-(4-henylsulfanylbenzoyl) heptylideneamino]benzoate, [1-[9-ethyl-6-(2-methylbenzoyl)carbazol-3-yl]ethylideneamino]acetate, and bis(2,4-cyclopentadienyl)bis[2,6-difluoro-3-(1-pyrryl)phenyl]titanium(IV).

1 to 5 parts by weight of the photoinitiator may be contained per 100 parts by weight of the polymer included in the hard coating composition.

The photoinitiator may be an initiator activated by ultraviolet light and may increase the hardness on the surface of the hard coating layer that includes the hard coating composition according to the embodiment of the present disclosure.

The hard coating composition may further contain an additive and/or a solvent.

The solvent included in the hard coating composition may include at least one of: 1-methoxy-2methyl-2propanol (PGM), 2-butanone, propylene glycol methyl ether acetate (PGMEA), propylene glycol ethyl ether acetate (PGEEA), propylene glycol methyl ether (PGME), propylene glycol propyl ether (PGPE), ethylene glycol monomethyl ether acetate, ethylene glycol monoethyl ether acetate, ethylene glycol monobutyl ether acetate, ethylene glycol monomethyl ether, ethylene glycol monoethyl ether, diethyl glycol methyl acetate, dipropylene glycol methyl ether, methyl ethoxypropionate, ethyl ethoxypropionate, ethyl acetate, butyl acetate, cyclohexanone, acetone, methyl isobutyl ketone, dimethylformamide, N,N′-dimethylacetamide, N-methylpyrrolidone, and toluene.

Additives well known in the art may be further contained unless they deteriorate the effects of the hard coating composition. For example, the hard coating composition according to an embodiment may further include at least one of a surfactant, an antioxidant, an antistatic agent, a leveling agent, and an ultraviolet absorber.

The hard coating layer 120 may be formed on the substrate 110 using the hard coating composition. Specifically, the hard coating layer 120 may be formed by coating the hard coating composition on the substrate 110 and then performing photocuring.

The coating process may involve at least one of roll coating, spin coating, deep coating, flow coating, and spray coating.

A UV or LED lamp may be used as the light source for photocuring. During photocuring, UV or an LED lamp may irradiate light with an intensity of 1,000 mJ/cm² to 5,000 mJ/cm².

The refractive index of the hard coating layer 120 formed using the hard coating composition according to the embodiment may range from 1.55 to 1.8. This is higher than the refractive index of 1.5 of the hard coating layer formed using a polymer such as a urethane resin, an epoxy resin, an acrylic resin and an acrylate resin, which are generally used in the hard coating layer.

The hard coating layer 120 may have such a thickness range that does not increase the repulsive force against the shape that is deformed as the display device 10 is folded.

The refractive layer 130 may be on the hard coating layer 120. The refractive layer may include a first refractive layer 131 and a second refractive layer 132 having different refractive indices.

The first refractive layer 131 may be on the hard coating layer 120. The first refractive layer 131 may be on the hard coating layer 120 by vacuum deposition. The first refractive layer 131 may have a higher refractive index than the second refractive layer 132. The refractive index of the first refractive layer 131 may range from, but is not limited to, 1.70 to 2.80. The first refractive layer 131 may have the same thickness as the second refractive layer 132. The first refractive layer 131 may have a higher refractive index than the hard coating layer 120.

The first refractive layer 131 may include a high refractive oxide. For example, the high refractive inorganic oxide may include at least one of: titanium niobate (Ti₄Nb₃O₃₅), titanium dioxide (TiO₂), zirconium dioxide (ZrO₂), lithium niobate (LiNbO₃), lithium tantalate (LiTaO₃), and titanium lanthanum (LaTiO₂).

The second refractive layer 132 may be on the first refractive layer 131. The second refractive layer 132 may be on the first refractive layer 131 by vacuum deposition. The second refractive layer 132 may have a lower refractive index than the first refractive layer 131. The second refractive layer 132 may have a lower refractive index than the hard coating layer 120. The refractive index of the second refractive layer 132 may range from, but is not limited to, 1.20 to 1.50. The second refractive layer 132 may have the same thickness as the first refractive layer 131.

The second refractive layer 132 may include a low refractive oxide. For example, the low-refractive oxide may include at least one of silicon resin, silica, and silicon dioxide (SiO₂).

In summary, a typical anti-reflection film has a multilayer structure of five or more layers by alternating a high-refractive layer and a low-refractive layer made of inorganic films utilizing the distributed Bragg reflector (DBR). In order to address such a shortcoming, according to the embodiment of the present disclosure, the refractive index of the hard coating layer 120 is higher than the refractive index of a hard coating layer formed using a polymer such as a urethane resin, an epoxy resin, an acrylic resin and an acrylate resin, the hard coating layer 120 can work as a component of a distributed Bragg reflector, as shown in FIG. 7. Therefore, even though the number of the refractive layers on the hard coating layer 120 to form the distributed Bragg reflector is reduced to three layers or less, the reflection characteristics of the anti-reflection film 100 can be maintained.

In addition, as the number of the refractive layers on the hard coating layer 120 is reduced, it is possible to prevent cracks from forming in the refractive layers of the anti-reflection film 100 due to compressive stress from the display device 10 being folded. Moreover, the number of fabrication processes can be reduced, reducing thus fabrication cost.

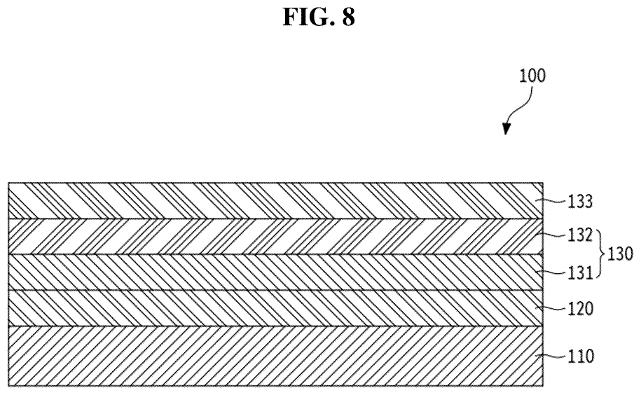

FIG. 8 is a cross-sectional view showing an anti-reflection film in a display device according to a second embodiment of the present disclosure.

The embodiment of FIG. 8 is substantially identical to the embodiment of FIG. 7 except that an anti-reflection film 100 further includes a third refractive layer 133; therefore, any redundant descriptions will be omitted

Referring to FIG. 8, the third refractive layer 133 may be on the second refractive layer 132. The third refractive layer 133 may be disposed on the second refractive layer 132 by vacuum deposition. The third refractive layer 133 may have a higher refractive index than the second refractive layer 132. The refractive index of the third refractive layer 133 may range from, but is not limited to, 1.70 to 2.80. The third refractive layer 133 may have the same thickness as the second refractive layer 132. It may be substantially identical to the first refractive layer. The third refractive layer 133 may have a higher refractive index than the hard coating layer 120.

Although the first refractive layer 131 of a high refractive index, the second refractive layer 132 of a low refractive index, and the third refractive layer 133 of a high refractive index according to the embodiment of the present disclosure have been described, the first refractive layer 131 of a low refractive index, the second refractive layer 132 of a high refractive index, and the third refractive layer 133 of a low refractive index may be used according to another embodiment. In the latter instance, the first refractive layer 131 may have a lower refractive index than the hard coating layer 120, the second refractive layer 132 may have a higher refractive index than the hard coating layer 120, and the third refractive layer 133 may have a lower refractive index than the hard coating layer 120.

Hereinafter, the embodiments of the present disclosure will be described in more detail. It should be understood that the embodiments of the present disclosure are merely illustrative and are not intended to limit the scope of the present disclosure.

1. Preparation of Inorganic Particles Surface-Treated with Silane Having Fluorene Skeleton

Initially, in Reaction Formula 1 below, 1.0 equivalent of 9,9-bis(4-allyloxyphenyl) fluorene and 2.0 equivalents of (3-mercaptopropyl)trimethoxysilane were mixed in a reaction vessel. Subsequently, 1-hydroxycyclohexyl phenyl ketone as a photoinitiator and tetrahydrofuran (THF) as a solvent were put in the reaction vessel and irradiated with ultraviolet light for two minutes to produce silane having a fluorene skeleton.

Subsequently, 3 equivalents of the silane having the fluorene skeleton and 65 equivalents of zirconia were subject to a bead mill process, to produce inorganic particles surface-treated with the silane having the fluorene skeleton.

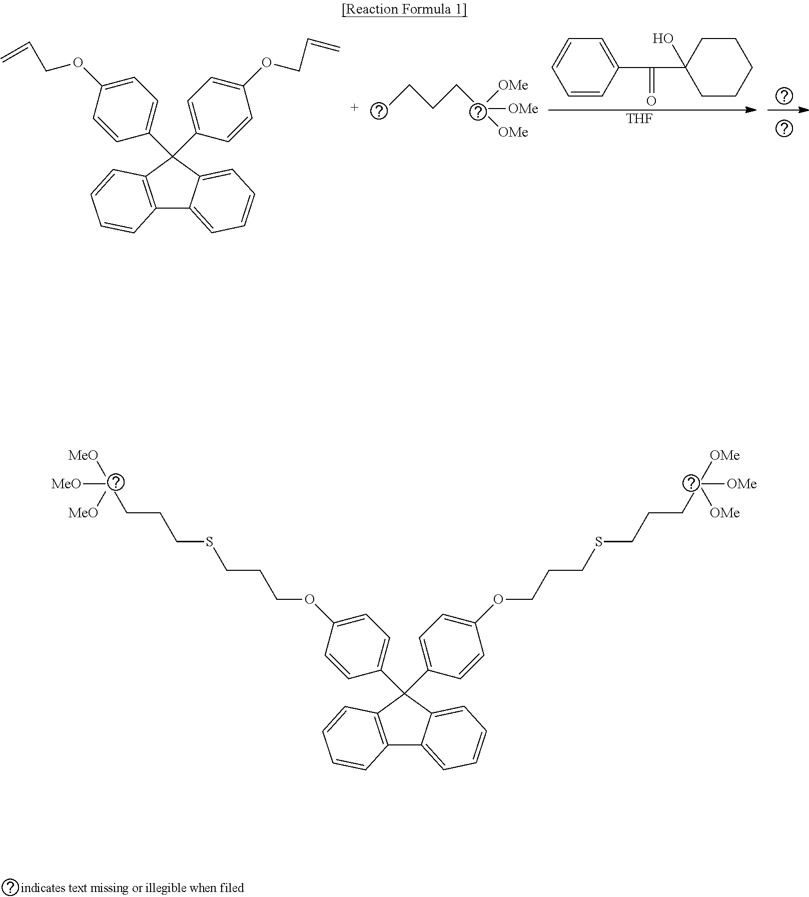 [SMILES: C=CCOc1ccc(C2(c3ccc(OCC=C)cc3)c3ccccc3-c3ccccc32)cc1 ; CCCCC(OC)(OC)OC ; O=C(c1ccccc1)C1(O)CCCCC1 ; "THF" ; COC(CCCSCCCOc1ccc(C2(c3ccc(OCCCSCCCC(OC)(OC)OC)cc3)c3ccccc3-c3ccccc32)cc1)(OC)OC]

### 2. Preparation of Hard Coating Composition

15 equivalents of silsesquioxane with random structure, 15 equivalents of 2-[3-(2-hydroxyethyl)-2,4,6-trioxo-5-(2-prop-2-enolyoxyethyl)-1,3,5-triazinan-1-yl]ethyl prop-2-enoate (isocyanurate diacrylate modified with ethanol), and the inorganic particles surface-treated with the silane having the fluorene skeleton were put in a reaction vessel and mixed. Subsequently, 1.5 equivalents of diphenyl(2,4,6-trimethylbenzoyl)phosphine oxide as a photoinitiator and 2-butanone as a solvent were put into to the reaction vessel and stirred for an hour, to produce a hard coating composition.

### 3. Preparation of Anti-Reflection Film

### 1) Example 1

The hard coating composition is spin-coated on a polymethyl methacrylate plastic substrate that has been cleaned via a cleaning process. The polymethyl methacrylate spin-coated with the hard coating composition was irradiated with a high-pressure mercury ultraviolet lamp at the power of 1,600 mJ/cm² for three minutes, to form a hard coating layer.

Subsequently, titanium niobate (Ti₄Nb₃O₃₅) was vacuum-deposited on the hard coating layer, to form a first refractive layer.

Subsequently, silicon dioxide (SiO₂) was vacuum-deposited on the first refractive layer to form a second refractive layer, thereby producing an anti-reflection film (two refractive layers in Example 1).

### 2) Example 2

A first refractive layer was formed by vacuum-depositing silicon dioxide (SiO₂) on the hard coating layer.

Subsequently, titanium niobate (Ti₄Nb₃O₃₅) was vacuum-deposited on the first refractive layer, to form a second refractive layer.

Subsequently, silicon dioxide (SiO₂) was vacuum-deposited on the first refractive layer to form a third refractive layer, thereby producing an anti-reflection film (three refractive layers in Example 2).

### [Evaluation]

### 1. Reflectance of Anti-Reflection Film

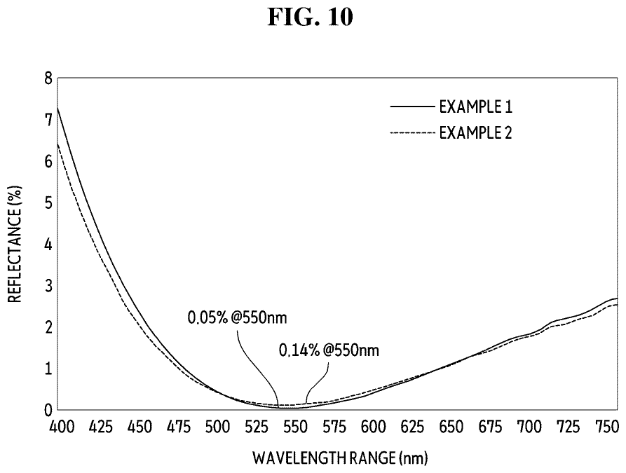

The reflectance of the anti-reflections film fabricated in Examples 1 and 2 versus the wavelength range was measured, and the results are shown in FIG. 10.

According to the results shown in FIG. 10, the reflectance of the anti-reflection film of Example 1 at the wavelength of 550 nm was 0.05%, and the reflectance of the anti-reflection film of Example 2 at the wavelength of 550 nm was be 0.14%.

Previously, low reflectance could be achieved by arranging a high-refractive layer and a low-refractive layer alternately in five or more layers using the distributed Bragg reflector. However, as a large number of layers are formed, the number of processes and cost increase, and cracks are likely to occur during folding. In contrast, according to the embodiment of the present disclosure, by applying the hard coating layer using the hard coating composition to the anti-reflection film, the reflectance of less than 1% can be achieved even with three or less refractive layers.

### 2. Radius of Curvature of Anti-Reflection Film

The radius of curvature was evaluated using a mandrel test. The bending characteristics were measured by wrapping an anti-reflection film having a hard coating layer formed therein around a test rod and varying the diameter of the rod to find the smallest diameter that creates no crack in the hard coating layer. The radius of curvature of the anti-reflection films fabricated in Examples 1 and 2 was 1.5 mm.

### 3. Evaluation of Folding Behavior of Anti-Reflection Film

The folding behavior was evaluated by repeatedly folding the anti-reflection film including the hard coating layer 200,000 times at room temperature to see breakage and change in the appearance.

As a result of the evaluation of the folding behavior, it was seen that there was no breakage or change in appearance after the anti-reflection films of Examples 1 and 2 according to the present disclosure had been folded 200,000 times at room temperature. Based on those data, it can be concluded that the anti-reflection film including the hard coating layer has good folding properties.

Although the embodiments of the present disclosure have been described with reference to the attached drawings, those skilled in the art will understand that the present disclosure can be implemented in other specific forms without changing the technical idea or essential features of the present disclosure. Therefore, it should be understood that the embodiments described above are examples and not restrictive.

What is claimed is:

1. A hard coating composition comprising: a polymer represented by Chemical Formula 1 below: 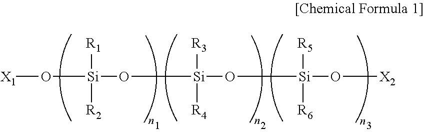
wherein at least two of R₁ to R₆ are represented by Chemical Formula 2 or 3, at least one is represented by Chemical Formula 4, the others are each independently H, a substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, a substituted or unsubstituted silyl group or a hydroxy group, the X₁ and X₂ are each independently H, halogen, a substituted or unsubstituted silyl group, and n₁, n₂ and n₃ are each independently an integer of 1 to 100, 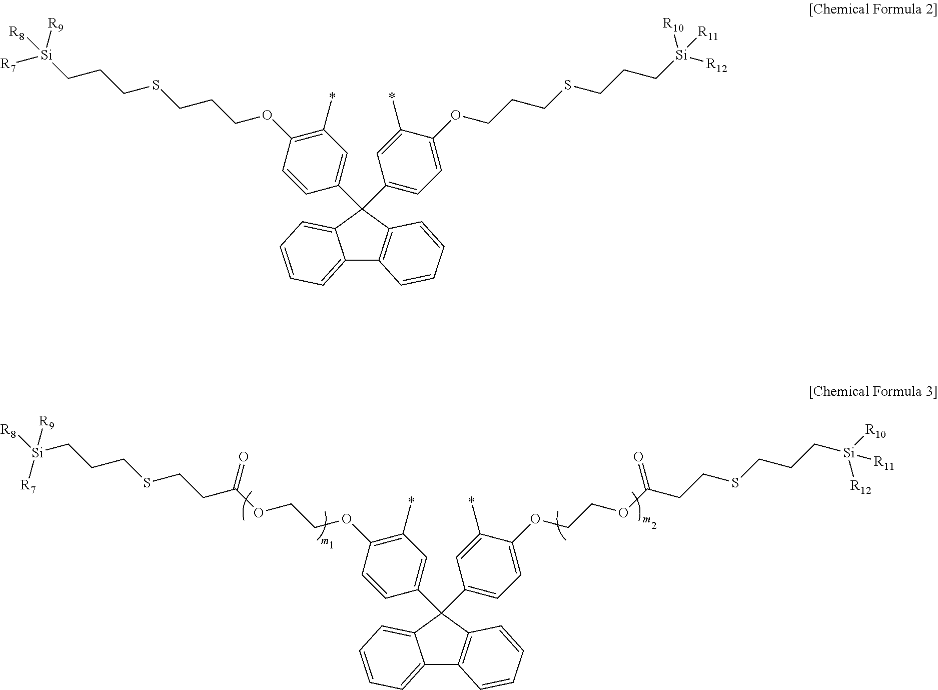
wherein R₇ to R₁₂ are each independently H, a substituted or unsubstituted C₁-C₆ alkyl group, or a substituted or unsubstituted C₁-C₆ alkoxy group, the R₇ to R₁₂ are coupled with the inorganic particles, and m₁ and m₂ are each independently an integer from 1 to 10, 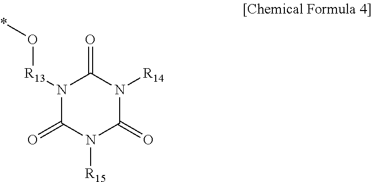
wherein R₁₃ is a substituted or unsubstituted C₁-C₆ alkyl group, at least one of R₁₄ and R₁₅ is 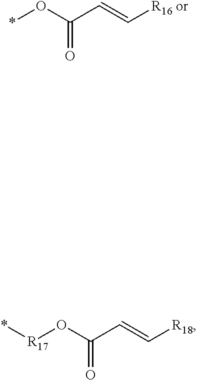
the other one is 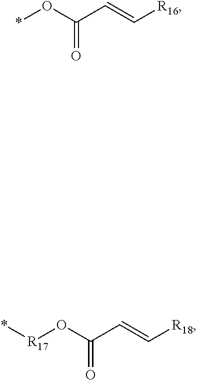
a substituted or unsubstituted C₁-C₆ alkyl group, a substituted or unsubstituted C₁-C₆ aryl group, a substituted or unsubstituted C₂-C₆ alkenyl group, a substituted or unsubstituted C₁-C₆ alkoxy group, or a substituted or unsubstituted C₄-C₁₀ acrylate, R₁₆ to R₁₈ are each independently H, a substituted or unsubstituted C₁-C₆ alkyl group, a substituted or unsubstituted C₁-C₆ alkenyl group, or a substituted or unsubstituted C₄-C₁₀ acrylate.

2. The composition of claim 1, further comprising: at least one photoinitiator.

3. The composition of claim 1, wherein the inorganic particles are at least one of ZrO₂, SiO₂, TiO₂, Al₂O₃, ZnO, AlN, and Si₃N₄.

4. An anti-reflection film comprising:
a substrate;
a hard coating layer on the substrate; and
a refractive layer on the hard coating layer,
wherein the hard coating layer is formed of a polymer derived from a mixture containing silsesquioxane, an isocyanurate compound and inorganic particles surface-treated with silane having a fluorene skeleton.

5. The anti-reflection film of claim 4, wherein 10 to 20 parts by weight of the silsesquioxane; 10 to 20 parts by weight of the isocyanurate compound; 1 to 10 parts by weight of the silane having a fluorene skeleton; and 40 to 70 parts by weight of the inorganic particles are contained per 100 parts by weight of the polymer.

6. The anti-reflection film of claim 4, wherein the polymer further comprises at least one photoinitiator, wherein the photoinitiator comprises 1 to 5 parts by weight per 100 parts by weight of the polymer.

7. The anti-reflection film of claim 4, wherein the silesesquioxane has a random structure, a ladder structure or a cage structure.

8. The anti-reflection film of claim 4, wherein the isocyanurate compound has at least one acrylate functional group.

9. The anti-reflection film of claim 8, wherein the isocyanurate compound has at least one C₁-C₆ alcohol group.

10. The anti-reflection film of claim 4, wherein the inorganic particles are at least one of ZrO2, SiO₂, TiO₂, Al₂O₃, ZnO, AlN, and Si₃N₄.

11. The anti-reflection film of claim 4, wherein a size of the inorganic particles ranges from 10 nm to 50 nm.

12. The anti-reflection film of claim 4, wherein the silane having the fluorene skeleton is represented by Chemical formula 5 or 6 below: 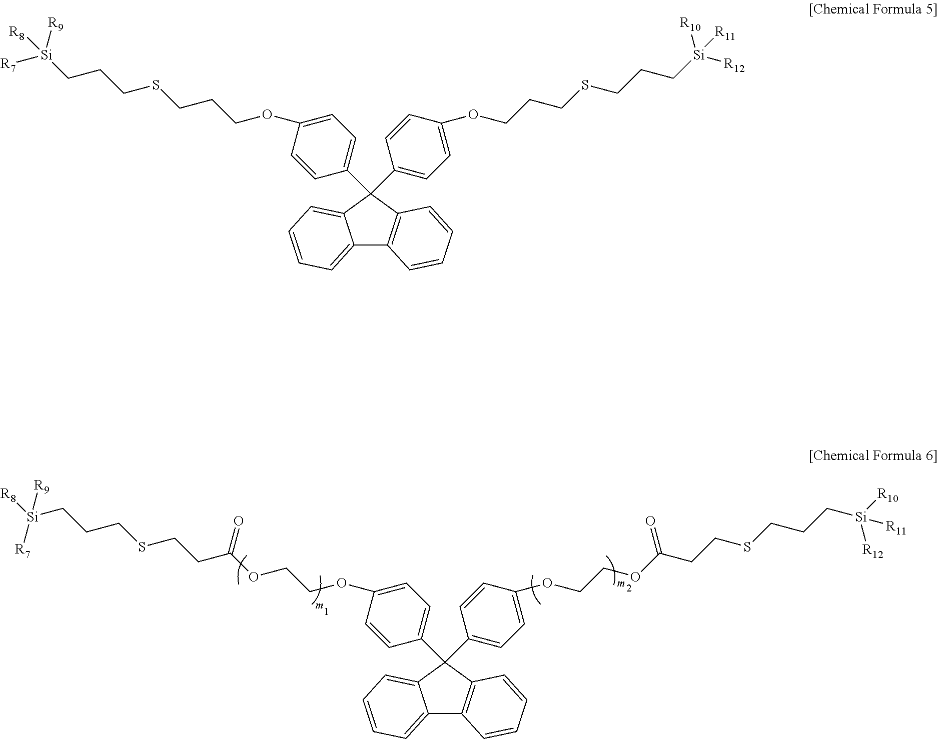
wherein R₇ to R₁₂ are each independently H, a substituted or unsubstituted C₁-C₆ alkyl group, or a substituted or unsubstituted C₁-C₆ alkoxy group, and each of m₁ and m₂ is independently an integer from 1 to 10.

13. The anti-reflection film of claim 12, wherein each of R₇ to R₁₂ is independently H, a methoxy group, or an ethoxy group.

14. The anti-reflection film of claim 4, wherein the refractive layer comprises a first layer, a second layer, and a third layer.

15. The anti-reflection film of claim 14, wherein the anti-reflection film has a reflectance of less than 1%.

16. The anti-reflection film of claim 4, wherein a refractive index of the hard coating layer ranges from 1.55 to 1.8.

17. An electronic device comprising:
a display panel;
a window member on the display panel; and
an anti-reflection film on the window member,
wherein the anti-reflection film comprises:
a substrate;
a hard coating layer on the substrate; and
a refractive layer on the hard coating layer,
wherein the hard coating layer is formed of a polymer derived from a mixture containing silsesquioxane, an isocyanurate compound and inorganic particles surface-treated with silane having a fluorene skeleton.

18. The electronic device of claim 17, wherein the refractive layer comprises a first layer, a second layer, and a third layer.

19. The electronic device of claim 17, wherein the anti-reflection film has a reflectance of less than 1%.

20. The electronic device of claim 17, wherein the hard coating layer has a refractive index of 1.55 to 1.8.
